(19) United States
(12) Patent Application Publication
(10) Pub. No.: US 2026/0255689 A1
(43) Pub. Date: Aug. 27, 2026

(54) ELECTROSTATIC DISCHARGE DISSIPATION FIELD-EFFECT TRANSISTOR (ESDDFET) HAVING A BODY WITHOUT LIGHTLY DOPED POCKET OR A HALO REGION TO INCREASE BREAKDOWN VOLTAGE

(71) Applicant: QUALCOMM Incorporated, San Diego, CA (US)

(72) Inventors: Hyunchul Jung, San Diego, CA (US); Ravi Pramod Kumar Vedula, San Diego, CA (US); Abhijeet Paul, San Diego, CA (US)

(21) Appl. No.: 19/062,344

(22) Filed: Feb. 25, 2025

(51) Int. Cl. H10D 89/60; H02H 9/04; H10W 42/60; H10W 44/20

(52) U.S. Cl. CPC H10D 89/811; H02H 9/046; H10D 89/921; H10W 42/60; H10W 44/20

(57) ABSTRACT

A radio frequency (RF) circuit is described. The RF circuit includes a first RF FET coupled in series to a first RF port and coupled in parallel to an RF common (RFC) port. The RF device also includes an electrostatic discharge (ESD) dissipation FET (ESDDFET) coupled to the RF common port. The ESDDFET includes a body region not comprising a lightly doped pocket in the body region, a drain region adjacent to a first side of the body region, a source region of the second polarity and adjacent to a second side of the body region opposite the first side and a gate region on the body region.

### TECHNICAL FIELD

The field of the disclosure relates to field-effect transistors (FETs), and more particularly to FET designs formed as silicon-on-insulator (SOI) substrates.

### BACKGROUND

Transistors are essential components in modern electronic devices, and large numbers of transistors are employed in integrated circuits (ICs) therein. For example, components such as central processing units (CPUs) and memory systems each employ a large quantity of transistors for logic circuits and memory devices. Transistors are also employed in radio frequency (RF) devices, such as modern smart phones, and other portable devices have extended the use of different wireless links with a variety of technologies in different RF bands.

Field-effect transistors (FETs) can be formed as silicon-on-insulator (SOI) substrate FETs and deployed in a semiconductor die (“die”). SOI substrate FETs are formed in thin layers of silicon that are isolated from the main body of the SOI wafer handle substrate by a layer of an electrical insulator, usually silicon dioxide also known as a buried oxide (BOX) layer. The silicon layer thickness ranges from several microns (i.e., micrometers (µm)) for electrical power switching devices to less than five hundred (500) Angstroms (Å) for high-performance microprocessors. FETs include gate, drain, source, and body terminals. The body terminal controls the electrical characteristics of the FET by affecting the threshold voltage and channel conductivity. Many discrete FETs internally couple the body terminal with the source terminal. In an N+ metal oxide silicon (NMOS) FET, the body terminal and source terminal are typically connected to ground. In a PMOS FET, the body terminal and source terminal are typically connected to the highest voltage in a circuit in which the PMOS FET is deployed. The performance of FETs is tuned by modifying the doping levels of lightly doped pockets (also known as lightly doped drain (LDD)) and halo regions disposed in the body. Modifying the doping of the lightly doped pockets impacts the reliability of the FETs, while modifying the doping levels of the halo region impacts the threshold voltage, Vt, for turning on the FET.

In practice, high performance RF FETs are manufactured using SOI substrates. A high performance RF FET is generally characterized by a high breakdown voltage and a low bipolar gain. Unfortunately, these performance parameters can affect the response of an RF FET to an electrostatic discharge (ESD) pulse. In particular, techniques that improve a breakdown voltage in RF switches negatively affect a tolerance of the RF FET to ESD events. Techniques for reducing the susceptibility of high performance RF FETs to ESD damage are desired.

### SUMMARY OF THE DISCLOSURE

Aspects disclosed herein include an electrostatic discharge dissipation (ESDD) field-effect transistor (FET) (ESDDFET) having a body without a lightly doped pocket or a halo region to increase breakdown voltage, and related methods thereto. The ESDDFET is coupled to a radio frequency (RF) switch to shunt the RF switch in response to a spurious signal such as an electrostatic discharge spike. Conventional approaches tune the performance of an electrostatic discharge dissipation transistor by varying the doping levels of a halo region or the lightly doped pockets (also known as lightly doped drain (LDD)) in the body. In so doing, a corresponding mask is required to adjust the desired doping levels differently from the other non-ESDDFETs fabricated on the same semiconductor die (“die”). Such a mask may cause an increase in fabrication costs for the die in which the transistor is fabricated by 2-3%. In one embodiment, recognizing that the ESDDFET may not need the same reliability as other transistors in the die since ESDDFETs are turned on rarely compared to non-ESDDFETs, the ESDDFET in accordance with the present disclosure does not include a lightly doped pocket which advantageously achieves higher breakdown voltage. In another embodiment, recognizing the size differential between ESDDFETs and non-ESDDFETs does not require modification of Vt in the ESDDFET, the ESDDFET in accordance with the present disclosure does not include a halo region and also advantageously achieves higher breakdown voltage by not including a halo region. Relative to other approaches which add process step(s) to increase the breakdown voltage in an ESDDFET, such as deploying a silicide area block (SAB) over the gate, source, and drain, an RF circuit deploying the ESDDFET in accordance with the present disclosure achieves a higher breakdown voltage without additional masks and, thus, can achieve an area savings of close to 40% on a die over those other techniques.

In an aspect, an RF circuit is provided. The RF circuit comprises a first RF field-effect transistor (FET) coupled in series to a first RF port and coupled in parallel to an RF common port and an electrostatic discharge dissipation (ESDD) FET (ESDDFET) coupled to the RF common port. The ESDDFET comprises a body region of a first polarity. The body region not comprising a lightly doped pocket in the body region. The ESDDFET further comprises a drain region of a second polarity and adjacent to a first side of the body region, a source region of the second polarity and adjacent to a second side of the body region opposite the first side, and a gate region on the body region.

In another aspect, a method of fabricating a RF circuit. The method comprises fabricating a first RF field effect transistor (FET) and fabricating an electrostatic discharge dissipation (ESDD) FET (ESDDFET). The step of fabricating the ESDDFET comprises fabricating a body region of a first polarity. The body region does not comprise a lightly doped pocket in the body region. The step of fabricating the ESDDFET further comprises fabricating a drain region of a second polarity and adjacent to a first side of the body region, fabricating a source region of the second polarity and adjacent to a second side of the body region opposite the first side, and fabricating a gate region on the body region. The method further comprises coupling the first RF FET in series to a first RF port and coupling the ESDDFET to a RF common port and in parallel with the first RF FET.

### BRIEF DESCRIPTION OF THE FIGURES

FIG. 1 is a schematic diagram illustrating an exemplary radio frequency (RF) circuit, including RF field-effect transistors (FETs) and electrostatic discharge dissipation (ESDD) FETs (ESDDFETs) having a body without a lightly doped pocket or a halo region to increase breakdown voltage;

FIG. 2 is a side view of an RF FET in the RF circuit of FIG. 1;

FIG. 3 is a side view of an exemplary ESDDFET of FIG. 1 having a body without a lightly doped pocket and a halo region to increase breakdown voltage;

FIG. 4 is a side view of another exemplary ESDDFET of FIG. 1 having a body without a lightly doped pocket and a halo region and a thicker gate oxide layer to increase breakdown voltage;

FIG. 5 is a side view of another exemplary ESDDFET of FIG. 1 having a body with a lightly doped pocket and without a halo region to increase breakdown voltage;

FIG. 6 is a side view of another exemplary ESDDFET of FIG. 1 having a body with a lightly doped pocket and a thicker gate oxide layer and without a halo region to increase breakdown voltage;

FIG. 7 is a top, layout view of an exemplary multi-finger ESDDFET having a body without a lightly doped pocket and a halo region to increase breakdown voltage;

FIG. 8 is a flowchart illustrating an exemplary fabrication process for fabricating an RF circuit including an ESDDFET having a body without a lightly doped pocket and a halo region to increase breakdown voltage including, but not limited to, the ESDDFETs in FIGS. 3-7;

FIGS. 9A-9B is a flowchart illustrating an exemplary fabrication process for fabricating an ESDDFET having a body without a lightly doped pocket and a halo region to increase breakdown voltage including, but not limited to, the ESDDFETs in FIGS. 3-7;

FIGS. 10A-10E are exemplary fabrication stages during fabrication of the ESDDFET according to the fabrication process in FIGS. 9A-9B; and

FIG. 11 is a block diagram of an exemplary wireless communications device that includes RF components comprising FETs wherein one or more FETs include an ESDDFET having a body without a lightly doped pocket to increase breakdown voltage, including, but not limited to, the ESDDFETs in FIGS. 1 and 3-7, and fabricated according to the exemplary fabrication process in FIGS. 8-9B.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

It should be understood that the terms “first,” “second,” “third,” etc., where used herein, are relative terms that may be used to distinguish between similarly named elements and are not meant to limit or imply a strict orientation and/or order unless otherwise specified. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example. For example, if a particular object that is discussed as at “top,” or “upper” or “above” another object, and such particular object is flipped 180 degrees, then such particular object would then be oriented as at “bottom,” or “lower” or “below” such other object.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Aspects disclosed herein include an electrostatic discharge dissipation (ESDD) field-effect transistor (FET) (ESDDFET) having a body without a lightly doped pocket or a halo region to increase breakdown voltage, and related methods thereto. The ESDDFET is coupled to a radio frequency (RF) switch to shunt the RF switch in response to a spurious signal such as an electrostatic discharge spike. Conventional approaches tune the performance of an electrostatic discharge dissipation transistor by varying the doping levels of a halo region or the lightly doped pockets (also known as lightly doped drain (LDD)) in the body. In so doing, a corresponding mask is required to adjust the desired doping levels differently from the other non-ESDDFETs fabricated on the same semiconductor die (“die”). Such a mask may cause an increase in fabrication costs for the die in which the transistor is fabricated by 2-3%. In one embodiment, recognizing that the ESDDFET may not need the same reliability as other transistors in the die since ESDDFETs are turned on rarely compared to non-ESDDFETs, the ESDDFET in accordance with the present disclosure does not include a lightly doped pocket which advantageously achieves higher breakdown voltage. In another embodiment, recognizing the size differential between ESDDFETs and non-ESDDFETs does not require modification of Vt in the ESDDFET, the ESDDFET in accordance with the present disclosure does not include a halo region and also advantageously achieves higher breakdown voltage by not including a halo region. Relative to other techniques which add process step(s) to increase the breakdown voltage in an ESDDFET, such as deploying a silicide area block (SAB) over the gate, source, and drain, an RF switch deploying the ESDDFET in accordance with the present disclosure achieves a higher breakdown voltage without additional masks and, thus, can achieve an area savings of close to 40% on a die over those other techniques.

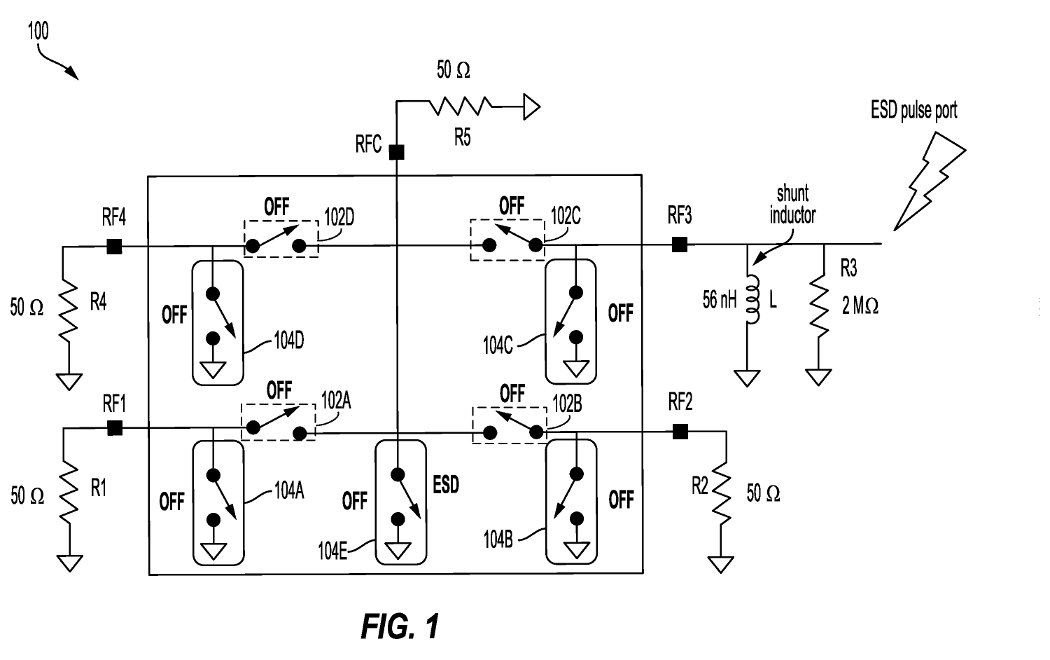

Turning to exemplary aspects, FIG. 1 is a schematic diagram illustrating an exemplary radio frequency (RF) circuit 100, including RF field-effect transistors (FETs) 102A-102D and electrostatic discharge dissipation (ESDD) FETs (ESDDFETs) 104A-104E having a body without a lightly doped pocket or a halo region to increase breakdown voltage. Each of the ESDDFETs 104A-104D is coupled in parallel to a corresponding RF FET 102A-102D to protect the corresponding RF FET 102A-102D from an electrostatic discharge (ESD) event. As shown in FIG. 1, each RF FET 102A-102D is coupled in series to a respective RF port RF1-RF4 and coupled in parallel to an RF common (RFC) port. In some aspects of the present disclosure, the RF circuit 100 also includes an ESDDFET 104E coupled to the RFC port. The RF circuit 100 routes RF signal(s) between any of the RF ports RF1-RF4 to the RFC port.

The RF circuit 100 also includes a first resistor R1 (e.g., a 50 Ohm (Ω) resistor) coupled to the RF1 port. In addition, a first ESDDFET 104A is coupled in a shunt connection between the RF1 port and the RF FET 102A. In some aspects of the present disclosure, the RF circuit 100 further includes a second RF FET 102B coupled in series to the first RF FET 102A and a second RF port (RF2). The second RF FET 102B is also coupled in parallel with the RFC port. In this example, the RF circuit 100 further includes a second ESDDFET 104B coupled in a shunt connection between the RF2 port and the second RF FET 102B. In addition, a second resistor R2 (e.g., a 50 Ohm resistor) is coupled to the RF2 port.

As shown in FIG. 1, the RF circuit 100 further includes a third RF FET 102C coupled in series to a third RF port (RF3) and coupled in parallel to the RFC port. In addition, the RF circuit 100 further includes a third ESDDFET 104C coupled in a shunt connection between the RF3 port and the third RF FET 102C. In some aspects of the present disclosure, the RF circuit 100 further includes a fourth RF FET 102D coupled in series to a fourth RF port (RF4) and coupled in parallel to the RFC port. In this example, the RF circuit 100 further includes a fourth ESDDFET 104D coupled in a shunt connection between the RF4 port and the fourth RF FET 102D. In addition, a fourth resistor R4 (e.g., a 50 Ω resistor) is coupled to the RF4 port, and a fifth resistor R5 (e.g., a 50 Ω resistor) is coupled to the RFC port.

As shown in FIG. 1, the RF circuit 100 includes a shunt inductor L (e.g., 56 nanohenries (nH)) coupled to the RF3 port. In addition, a third resistor R3 (e.g., 2 megaohms (MΩ)) is coupled to the RF3 port. In this example, the third RF3 port is configured as an ESD pulse port. In response to an ESD pulse, the ESDDFET 104E and the four shunt ESDDFETs 104A-104D may operate to protect the RF circuit 100. In particular, the inherent resistance provided by the ESDDFETs 104A-104E provides a negative feedback for both positive and negative polarity ESD pulses, which improves an overall ESD immunity of the RF circuit 100.

IEC 61000-4-2 is an electrostatic discharge (ESD) immunity standard from the International Electrotechnical Commission (IEC). As used in the mobile phone industry, the IEC 61000-4-2 standard is designed to test immunity from humans touching an antenna and damaging a radio frequency (RF) front end of a mobile phone. The IEC 61000-4-2 standard differs from the human-body model (HBM) and the charged-device (CDC) model because the IEC 61000-4-2 standard involves higher frequency components and lower series resistance relative to the HBM and CDC models. In particular, testing according to the IEC 61000-4-2 standard is performed with both positive and negative polarity pulses applied to the RF ports of the RF front end of a mobile phone.

Beneficially, the ESDDFETs 104A-104E provide improved IEC immunity over other approaches including silicide area block ESD FETs. In addition, a linearity of the ESDDFETs 104A-104E is approximately 10% better than the standard RF FET in the same technology area. Furthermore, a breakdown voltage of the ESDDFETs 104A-104E is approximately 0.1 V (or 3%) lower than the standard RF switch, which is negligible for RF applications, according to aspects of the present disclosure. The area occupied by the structures of the ESDDFETs 104A-104E may be .023 mm² in some implementations which is approximately 60% of the area occupied by a conventional ESDDFET deploying a silicide area block (SAB) over the gate, source, and drain (“SAB device”). It is noted that the values (e.g., 56 nH, 50 Ω, etc.) shown in FIG. 1 are merely non-limiting examples. Other sized components are also contemplated. Employing lightly doped pockets and halo regions are so ingrained in the design of other approaches which add process steps to increase the breakdown voltage in an ESD FET, it is not uncommon that descriptions of those approaches presume the existence of lightly doped pockets and halo regions such that those descriptions do not highlight or even mention lightly doped pockets or halo regions. The RF circuit 100 may be deployed in a die in a front end module.

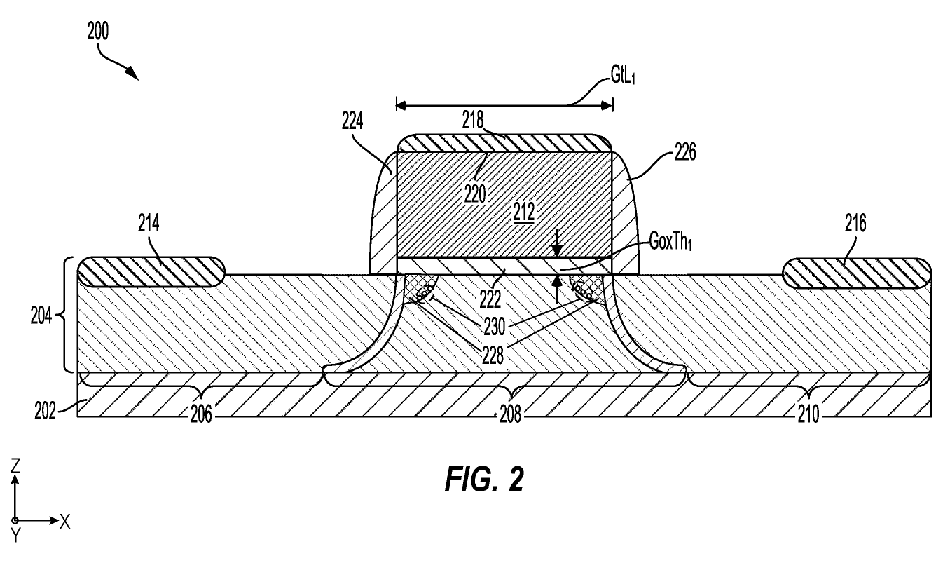

FIG. 2 is a side view of an RF FET 200 in the RF circuit of FIG. 1. The RF FET 200 may be any or all of the RF FETs 102A-102D. In this example, the RF FET 200 includes a buried oxide (BOX) layer 202 on which a semiconductor on insulator (SOI) layer 204 is formed. In this implementation, the SOI layer 204 includes a source region 206, a body region 208, a drain region 210, and a gate region 212. The source region 206 includes a source contact 214, and the drain region 210 includes a drain contact 216. In this configuration, the gate region 212 includes a gate contact 218 on a surface 220 of the gate region 212 opposite a gate oxide (Gox) layer 222 on the SOI layer 204. The gate region 212 also includes a first sidewall insulator spacer 224 and a second sidewall insulator spacer 226. The body region 208 includes lightly doped pockets 228 and halo regions 230. In practice, a high breakdown voltage and a low bipolar gain are characteristics of a high performance RF FET including the switch FET 200. The gate oxide layer 222 has a thickness layer GoxTh₁. The gate region 212 has a gate length GtL₁. Unfortunately, these device characteristics of high performance RF FETs increase their susceptibility to IEC ESD damage and require an ESDDFET to protect from an ESD event.

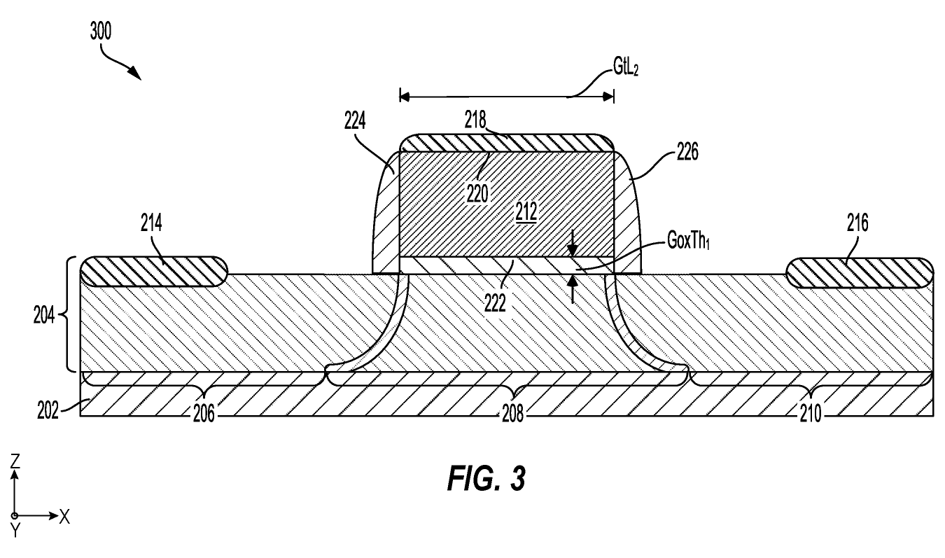

FIG. 3 is a side view of an exemplary ESDDFET 300 of FIG. 1 having a body without a lightly doped pocket and a halo region to increase breakdown voltage. The ESDDFET 300 may be any or all of the ESDDFETs 104A-104E. Common elements between the exemplary ESDDFET 300 in FIG. 3 and the RF FET 200 in FIG. 2 are shown with common element numbers. The ESDDFET 300 specifically does not include a lightly doped pocket such as the lightly doped pockets 228 in FIG. 2 and does not include a halo region such as the halo regions 230 in FIG. 2. The gate region 212 in FIG. 3 has a gate length GtL₂ where GtL₂ is anywhere between 1.2 and 9 times the length of GtL₁.

Without a lightly doped pocket, the ESDDFET 300 advantageously achieves higher breakdown voltage. Recognizing the size differential of the gate lengths between the ESDDFET 300 and the RF FET 200, the ESDDFET 300 does not require modification of threshold voltage, Vt, which is conventionally tuned with a halo region. As such, the ESDDFET 300 also does not include a halo region.

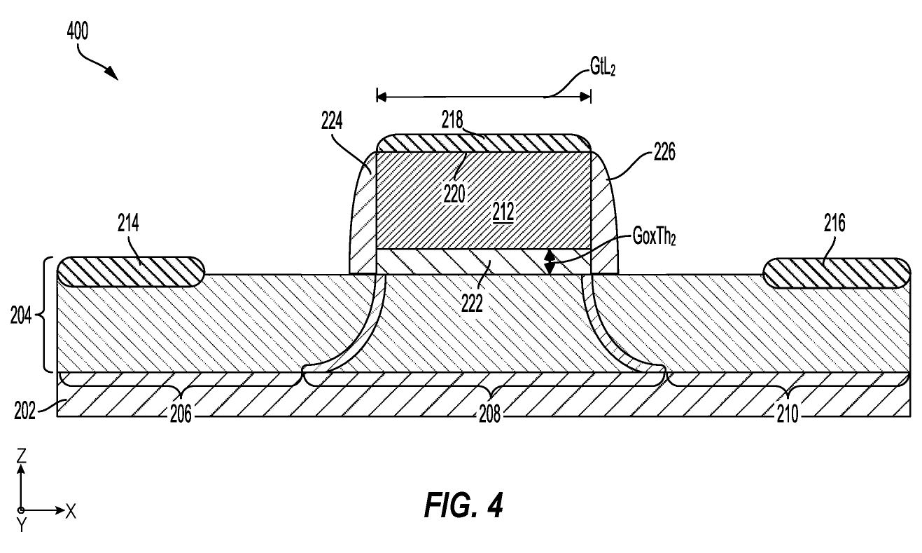

FIG. 4 is a side view of another exemplary ESDDFET 400 of FIG. 1 having a body without a lightly doped pocket and a halo region and having a thicker gate oxide layer to increase breakdown voltage. The ESDDFET 400 may be any or all of the ESDDFETs 104A-104E. Common elements between the exemplary ESDDFET 400 in FIG. 4 and the RF FET 200 in FIG. 2 and the ESDDFET 300 in FIG. 3 are shown with common element numbers. The gate oxide layer 222 in FIG. 4 has a gate oxide thickness, GoxTh₂, which is at least 1.4 times thicker than GoxTh₁ in FIGS. 2 and 3. In addition to the advantages of the ESDDFET 300, the thicker GoxTh₂ of ESDDFET 400 advantageously improves breakdown voltage drain (BVD) performance and meeting or exceeding standard requirements in IEC 61000-4-2.

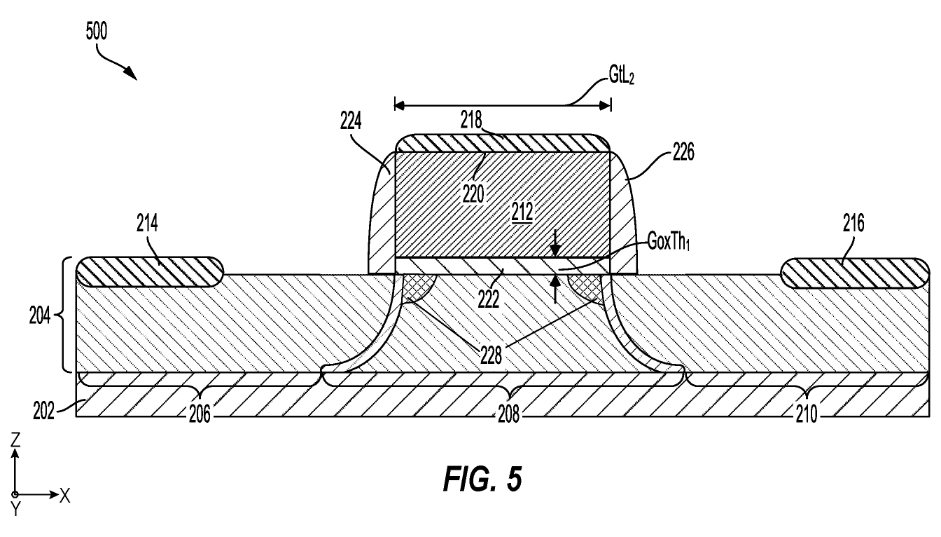

FIG. 5 is a side view of another exemplary ESDDFET 500 of FIG. 1 having a body with a lightly doped pocket and without a halo region to increase breakdown voltage. The ESDDFET 500 may be any or all of the ESDDFETs 104A-104E. Common elements between the exemplary ESDDFET 500 in FIG. 5 and the RF FET 200 in FIG. 2 and the ESDDFETs 300, 400 in FIGS. 3, 4, respectively, are shown with common element numbers. The gate oxide layer 222 in FIG. 5 has a gate oxide thickness, GoxTh₁. The ESDDFET 500 includes lightly doped pockets 228 and does not include a halo region such as the halo regions 230 in FIG. 2.

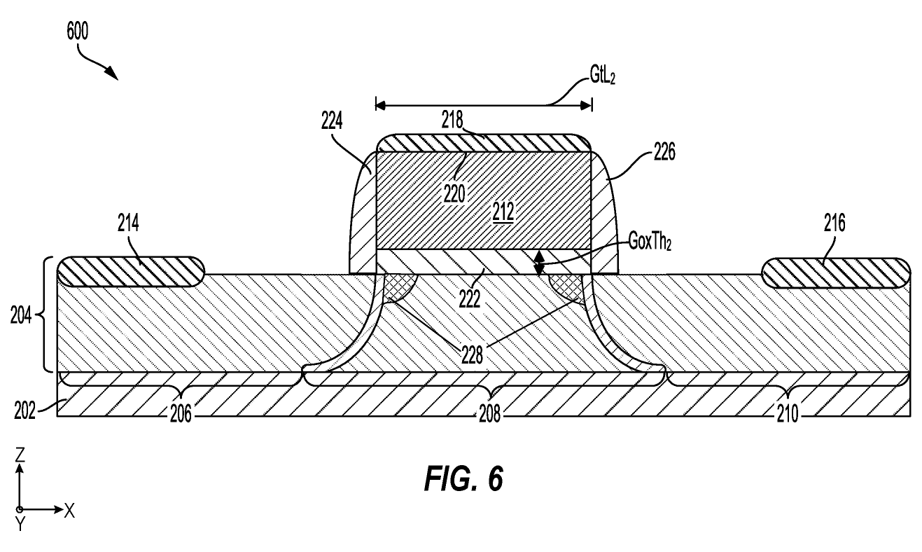

FIG. 6 is a side view of another exemplary ESDDFET 600 of FIG. 1 having a body with a lightly doped pocket and a thicker gate oxide layer and without a halo region to increase breakdown voltage. The ESDDFET 600 may be any or all of the ESDDFETs 104A-104E. Common elements between the exemplary ESDDFET 600 in FIG. 6 and the RF FET 200 in FIG. 2 and ESDDFETs 300, 400, 500 in FIGS. 3-5, respectively, are shown with common element numbers. The gate oxide layer 222 in FIG. 6 has a gate oxide thickness, GoxTh₂. The ESDDFET 600 includes lightly doped pockets 228 and does not include a halo region such as the halo region 230 in FIG. 2.

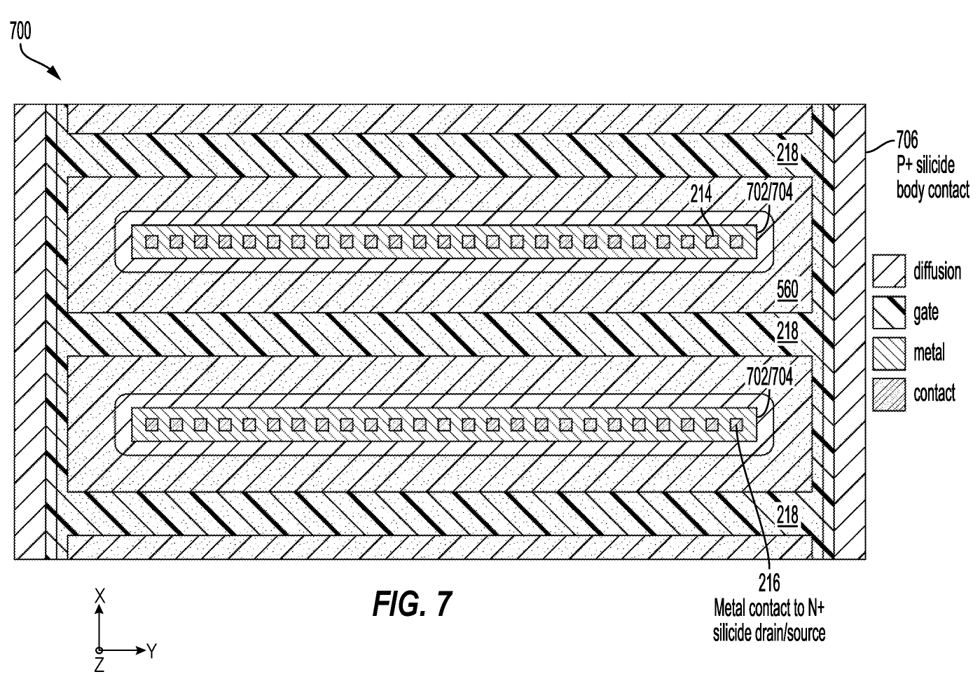

FIG. 7 is a top, layout view of an exemplary multi-finger ESDDFET 700 having a body without a lightly doped pocket and a halo region to increase breakdown voltage. The multi-finger ESDDFET 700 may represent a top view of the ESDDFETs 104A-104E of FIG. 1 or the ESDDFETs 300, 400, 500 and 600 in FIGS. 3, 4, 5 and 6, respectively, in a multi-finger configuration. Common elements between the ESDDFET 700 in FIG. 7 and the RF FET 200 in FIG. 2 and ESDDFETs 300, 400, 500, and 600 in FIGS. 3-6, respectively, are shown with common element numbers. The ESDDFET 700 includes multiple gate contacts 218 as well as source/drain silicide regions 702/704 and body regions (e.g., 208). In addition, source/drain contacts 214/216 (e.g., fabricated in a middle-of-line (MOL) interconnect layer) to the source/drain silicide regions 702/704, as well as a body silicide region 706 (e.g., a P+ body silicide region), are shown. All of the exemplary ESDDFETS 300, 400, 500, 600, and 700 in FIGS. 3, 4, 5, 6 and 7, respectively, are illustrated as NFETs where the source region 206 and drain region 210 are doped n+ and the body region 208 is doped p+. The same advantages of these exemplary ESDDFETs 300, 400, 500, 600, and 700 apply to PFETs where the source region 206 and drain region 210 are doped p+ and the body region 208 is doped n+.

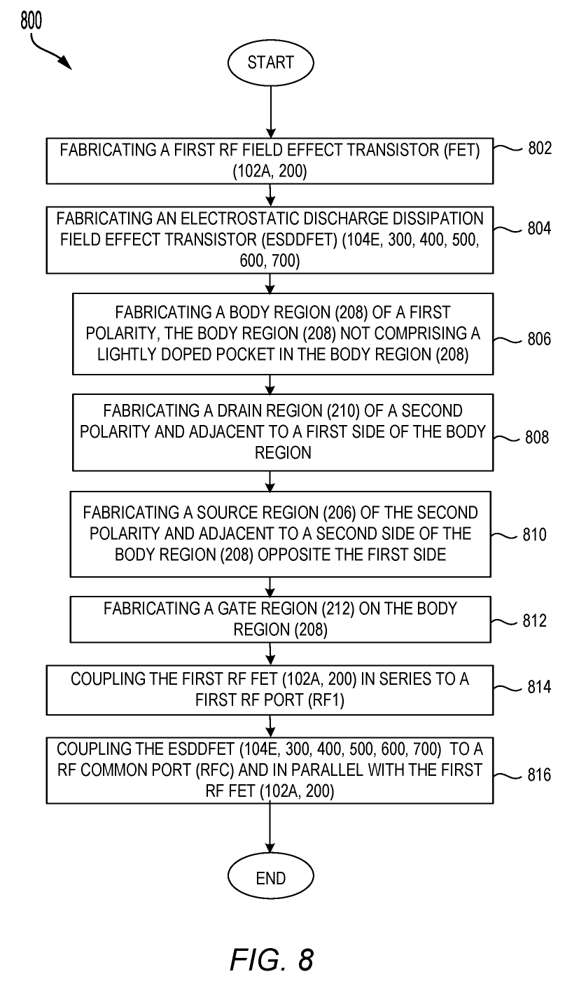

An RF circuit including, but not limited to, RF circuit 100 which includes an ESDDFET having a body without a lightly doped pocket and a halo region to increase breakdown voltage including, but not limited to, the ESDDFETs 300, 400, 500, 600, and 700, in FIGS. 3-6 and 7 can be fabricated by different fabrication processes. FIG. 8 is a flowchart illustrating an exemplary fabrication process for fabricating an RF circuit including an ESDDFET having a body without a lightly doped pocket and a halo region to increase breakdown voltage including, but not limited to, the ESDDFETs in FIGS. 3-7. In this regard, a first exemplary step in the fabrication process 800 of FIG. 8 can include fabricating a first RF FET 102A, 200 (block 802). A next step in the fabrication process 800 can include fabricating an electrostatic discharge dissipation FET (ESDDFET) 104E, 300, 400, 500, 600, and 700 (block 804). A step in fabricating the ESDDFET 104E, 300, 400, 500, 600, and 700 may include fabricating a body region 208 of a first polarity, the body region 208 not comprising a lightly doped pocket in the body region 208 (block 806). A next step in fabricating the ESDDFET 104E, 300, 400, 500, 600, and 700 may include fabricating a drain region 210 of a second polarity and adjacent to a first side of the body region 208 (block 808). A next step in fabricating the ESDDFET 104E, 300, 400, 500, 600, and 700 may include fabricating a source region 206 of the second polarity and adjacent to a second side of the body region 208 opposite the first side (block 810). A next step in fabricating the ESDDFET 104E, 300, 400, 500, 600, and 700 may include fabricating a gate region 212 on the body region 208 (block 812). A next step in the fabrication process 800 can include coupling the first RF FET 102A, 200 in series to a first RF port RF1 (block 814). A next step in the fabrication process 800 can include coupling the ESDDFET 104E, 300, 400, 500, 600, and 700 to a RF common port, RFC, and in parallel with the first RF FET 102A, 200 (block 816).

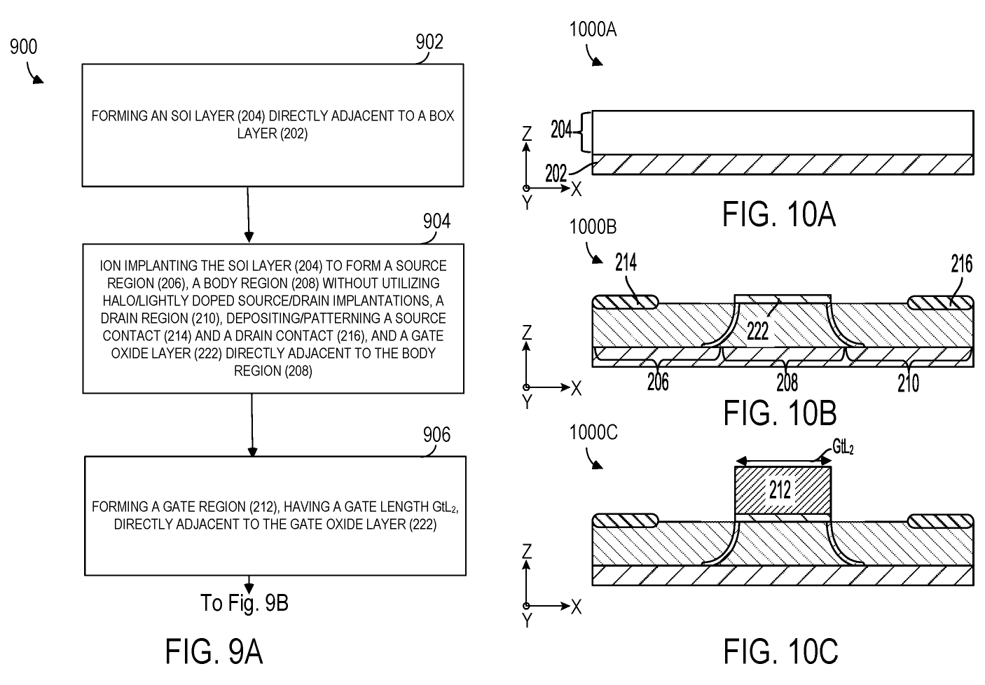

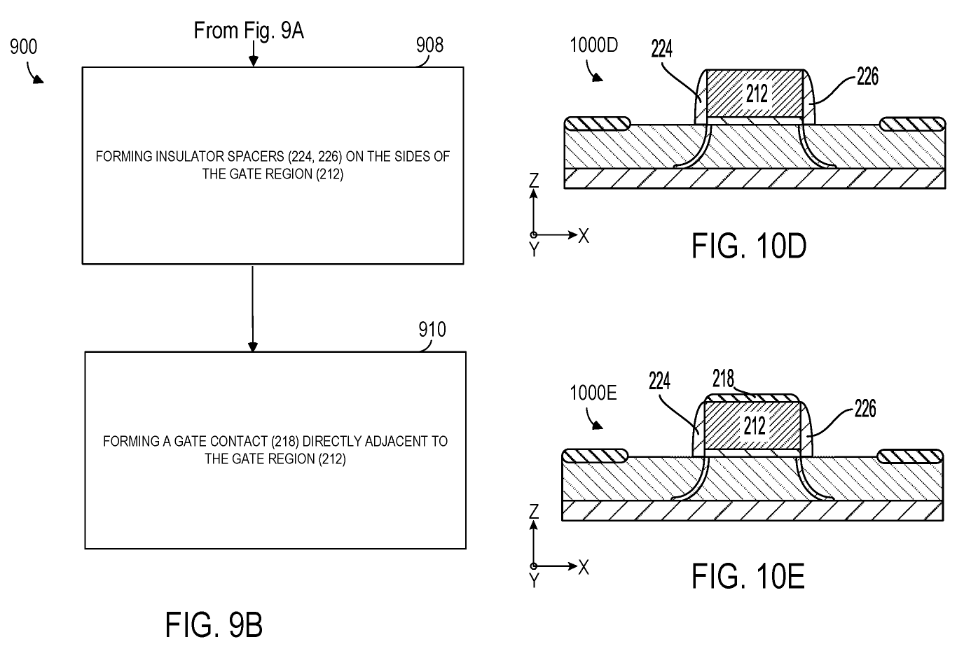

Other fabrication processes can also be employed to fabricate an RF circuit including, but not limited to, the RF circuit described in FIG. 1, wherein the RF circuit includes an ESDDFET having a body without a lightly doped pocket and a halo region to increase breakdown voltage including, but not limited to the ESDDFETs 300, 400, 500, 600, and 700 in FIGS. 3-7. In this regard, FIGS. 9A-9B is a flowchart illustrating an exemplary fabrication process 900 for fabricating an ESDDFET having a body without a lightly doped pocket and a halo region to increase breakdown voltage including, but not limited to, the ESDDFETs in FIGS. 3-7. FIGS. 10A-10E are exemplary fabrication stages during fabrication of the ESDDFET according to the fabrication process in FIGS. 9A-9B.

In this regard, as shown in fabrication stage 1000A in FIG. 10A, an exemplary step in the fabrication process 900 of FIG. 9 can include forming an SOI layer 204 directly adjacent to a BOX layer 202 (block 902 in FIG. 9A). As shown at assembly stage 1000B in FIG. 10B, a next step in the fabrication process 900 can include ion implanting the SOI layer 204 to form a source region 206, a body region 208 without utilizing halo/lightly doped source/drain implantations, a drain region 210, depositing/patterning a source contact 214 and a drain contact 216, and a gate oxide layer 222 directly adjacent to the body region 208 (block 904 in FIG. 9A). As shown at assembly stage 1000C in FIG. 10C, a next step in the fabrication process 900 can include forming a gate region 212 directly adjacent to the gate oxide layer 222 (block 906 in FIG. 9A). The gate region 212 has a length GtL₂ which is between 1.2 and 9 times the length of a RF FET formed on the same SOI layer 204. As shown at assembly stage 1000D in FIG. 10D, a next step in the fabrication process 900 can include forming sidewall insulator spacers 224, 226 on the sides of the gate region 212 (block 908 in FIG. 9B). As shown at assembly stage 1000E in FIG. 10E, a next step in the fabrication process 900 can include forming a gate contact 218 directly adjacent to the gate region 212 (block 910 in FIG. 9B).

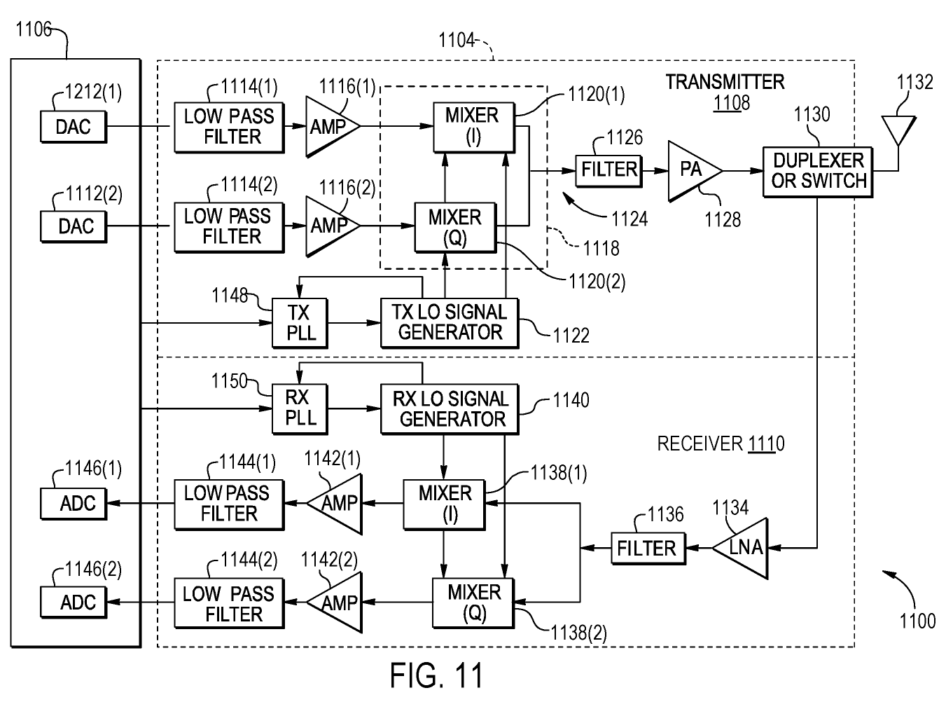

FIG. 11 is a block diagram of an exemplary wireless communications device that includes RF components comprising FETs wherein one or more FETs include an ESDDFET having a body without a lightly doped pocket to increase breakdown voltage, including, but not limited to, the ESDDFET in FIGS. 1 and 3-7, and fabricated according to the exemplary fabrication process in FIGS. 8-9.

As shown in FIG. 11, the wireless communications device 1100 includes a transceiver 1104 and a data processor 1106. The data processor 1106 may include a memory to store data and program codes. The transceiver 1104 includes a transmitter 1108 and a receiver 1110 that support bi-directional communications. In general, the wireless communications device 1100 may include any number of transmitters 1108 and/or receivers 1110 for any number of communication systems and frequency bands. All or a portion of the transceiver 1104 may be implemented on one or more analog ICs, RF ICs (RFICs), mixed-signal ICs, etc.

The transmitter 1108 or the receiver 1110 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1110. In the direct-conversion architecture, a signal is frequency-converted between RF and baseband in one stage. The super-heterodyne and direct-conversion architectures may use different circuit blocks and/or have different requirements. In the wireless communications device 1100 in FIG. 11, the transmitter 1108 and the receiver 1110 are implemented with the direct-conversion architecture.

In the transmit path, the data processor 1106 processes data to be transmitted and provides I and Q analog output signals to the transmitter 1108. In the exemplary wireless communications device 1100, the data processor 1106 includes digital-to-analog converters (DACs) 1112(1), 1112(2) for converting digital signals generated by the data processor 1106 into the I and Q analog output signals (e.g., I and Q output currents) for further processing.

Within the transmitter 1108, lowpass filters 1114(1), 1114(2) filter the I and Q analog output signals, respectively, to remove undesired signals caused by the prior digital-to-analog conversion. Amplifiers (AMPs) 1116(1), 1116(2) amplify the signals from the lowpass filters 1114(1), 1114(2), respectively, and provide I and Q baseband signals. An upconverter 1118 upconverts the I and Q baseband signals with I and Q transmit (TX) local oscillator (LO) signals through mixers 1120(1), 1120(2) from a TX LO signal generator 1122 to provide an upconverted signal 1124. A filter 1126 filters the upconverted signal 1124 to remove undesired signals caused by the frequency up-conversion as well as noise in a receive frequency band. A power amplifier (PA) 1128 amplifies the upconverted signal 1124 from the filter 1126 to obtain the desired output power level and provides a transmit RF signal. The transmit RF signal is routed through a duplexer or switch 1130 and transmitted via an antenna 1132.

In the receive path, the antenna 1132 receives signals transmitted by base stations and provides a received RF signal, which is routed through the duplexer or switch 1130 and provided to a low noise amplifier (LNA) 1134. The duplexer or switch 1130 is designed to operate with a specific receive (RX)-to-TX duplexer frequency separation, such that RX signals are isolated from TX signals. The received RF signal is amplified by the LNA 1134 and filtered by a filter 1136 to obtain a desired RF input signal. Down-conversion mixers 1138(1), 1138(2) mix the output of the filter 1136 with I and Q RX LO signals (i.e., LO_I and LO_Q) from an RX LO signal generator 1140 to generate I and Q baseband signals. The I and Q baseband signals are amplified by AMPs 1142(1), 1142(2) and further filtered by lowpass filters 1144(1), 1144(2) to obtain I and Q analog input signals, which are provided to the data processor 1106. In this example, the data processor 1106 includes analog-to-digital converters (ADCs) 1146(1), 1146(2) for converting the analog input signals into digital signals to be further processed by the data processor 1106.

In the wireless communications device 1100 of FIG. 11, the TX LO signal generator 1122 generates the I and Q TX LO signals used for frequency up-conversion, while the RX LO signal generator 1140 generates the I and Q RX LO signals used for frequency down-conversion. Each LO signal is a periodic signal with a particular fundamental frequency. A TX phase-locked loop (PLL) circuit 1148 receives timing information from the data processor 1106 and generates a control signal used to adjust the frequency and/or phase of the TX LO signals from the TX LO signal generator 1122. Similarly, an RX PLL circuit 1150 receives timing information from the data processor 1106 and generates a control signal used to adjust the frequency and/or phase of the RX LO signals from the RX LO signal generator 1140.

A semiconductor die including transistors wherein one or more transistors having an independently controlled body contact region which has a reduced length to reduce parasitic capacitance as disclosed in aspects described herein may be provided in or integrated into an IC and deployed in any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. A radio frequency (RF) circuit, comprising:

a first RF field-effect transistor (FET) coupled in series to a first RF port and coupled in parallel to an RF common port; and

an electrostatic discharge dissipation (ESDD) FET (ESDDFET) coupled to the RF common port, the ESDDFET, comprising:

a body region of a first polarity, the body region not comprising:

a lightly doped pocket in the body region;

a drain region of a second polarity and adjacent to a first side of the body region;

a source region of the second polarity and adjacent to a second side of the body region opposite the first side; and

a gate region on the body region.

2. The RF circuit of clause 1, wherein:

the first RF FET further comprises:

a first RF FET gate oxide layer having a first thickness; and

the gate region comprises:

a gate; and

a gate oxide layer on the body region, the gate oxide layer having a second thickness at least 1.4 times thicker than the first thickness.

3. The RF circuit of clause 1 or 2, wherein the body region comprises:

a first lightly doped pocket of the second polarity in the body region adjacent to the drain region; and

a second lightly doped pocket of the second polarity in the body region adjacent to the source region,

wherein the body region does not comprise:

a halo region in the body region.

4. The RF circuit of clause 3, wherein:

the first RF FET further comprises:

a first RF FET gate oxide layer having a first thickness; and

the gate region comprises:

a gate; and

a gate oxide layer on the body region, the gate oxide layer having a second thickness at least 1.4 times thicker than the first thickness.

5. The RF circuit of any of clauses 1-4, wherein:

the first polarity is n+; and

the second polarity is p+.

6. The RF circuit of any of clauses 1-5, wherein:

the first RF FET has a first RF FET gate length; and

the gate region has a gate length between 1.2 and 9 times the first RF FET gate length.

7. The RF circuit of any of clauses 1-6, further comprising a first shunt ESDDFET coupled in a shunt connection between the first RF port and the first RF FET.

8. The RF circuit of any of clauses 1-7, further comprising a second RF FET coupled in series to the first RF FET and a second RF port, and coupled in parallel to the RF common port.

9. The RF circuit of clause 8, further comprising a second shunt ESDDFET coupled in a shunt connection between the second RF port and the second RF FET.

10. The RF circuit of clause 8 or 9, wherein the second RF port comprises an electrostatic discharge (ESD) pulse port.

11. The RF circuit of any of clauses 1-10, integrated in an RF front end module.

12. The RF circuit of clause 11, wherein the RF front end module is incorporated in at least one of a music player, a video player, an entertainment unit, a navigation device, a communications device, a personal digital assistant (PDA), a fixed location data unit, a mobile phone, and a portable computer.

13. A method for fabricating a radio frequency (RF) circuit, comprising:

fabricating a first RF field effect transistor (FET);

fabricating an electrostatic discharge dissipation (ESDD) FET (ESDDFET), comprising;

fabricating a body region of a first polarity, the body region not comprising:

a lightly doped pocket in the body region;

fabricating a drain region of a second polarity and adjacent to a first side of the body region;

fabricating a source region of the second polarity and adjacent to a second side of the body region opposite the first side; and

fabricating a gate region on the body region;

coupling the first RF FET in series to a first RF port; and

coupling the ESDDFET to a RF common port and in parallel with the first RF FET.

14. The method of clause 13, wherein:

fabricating the first RF FET further comprises:

fabricating a first RF FET gate oxide layer having a first thickness; and

fabricating the ESDDFET further comprises:

fabricating a gate oxide layer on the body region, the gate oxide layer having a second thickness at least 1.4 times thicker than the first thickness.

15. The method of clause 13 or 14, wherein the body region comprises:

a first lightly doped pocket of the second polarity in the body region adjacent to the drain region; and

a second lightly doped pocket of the second polarity in the body region adjacent to the source region,

wherein the body region does not comprise:

a halo region in the body region.

16. The method of any of clauses 13-15, wherein:

fabricating the first RF FET further comprises:

fabricating an RF FET gate having a first RF FET gate length; and

fabricating the ESDDFET further comprises:

fabricating an ESDDFET gate having a gate length between 1.2 and 9 times the first RF FET gate length.

17. The method of any of clauses 13-16, further comprising:

fabricating a first shunt ESDDFET; and

coupling the first shunt ESDDFET in a shunt connection between the first RF port and the first RF FET.

18. The method of any of clauses 13-17, further comprising:

fabricating a second RF FET;

coupling the second RF FET in series to the first RF FET and a second RF port; and

coupling the second RF FET in parallel to the RF common port.

19. The method of clause 18, further comprising:

fabricating a second shunt ESDDFET; and

coupling the second shunt ESDDFET in a shunt connection between the second RF port and the second RF FET.

20. The method of clause 18 or 19, wherein the second RF port comprises an electrostatic discharge (ESD) pulse port.

What is claimed is:

1. A radio frequency (RF) circuit, comprising:
a first RF field-effect transistor (FET) coupled in series to a first RF port and coupled in parallel to an RF common port; and
an electrostatic discharge dissipation (ESDD) FET (ESDDFET) coupled to the RF common port, the ESDDFET, comprising:
a body region of a first polarity, the body region not comprising:
a lightly doped pocket in the body region;
a drain region of a second polarity and adjacent to a first side of the body region;
a source region of the second polarity and adjacent to a second side of the body region opposite the first side; and
a gate region on the body region.

2. The RF circuit of claim 1, wherein:
the first RF FET further comprises:
a first RF FET gate oxide layer having a first thickness; and
the gate region comprises:
a gate; and
a gate oxide layer on the body region, the gate oxide layer having a second thickness at least 1.4 times thicker than the first thickness.

3. The RF circuit of claim 1, wherein the body region comprises:
a first lightly doped pocket of the second polarity in the body region adjacent to the drain region; and
a second lightly doped pocket of the second polarity in the body region adjacent to the source region,
wherein the body region does not comprise:
a halo region in the body region.

4. The RF circuit of claim 3, wherein:
the first RF FET further comprises:
a first RF FET gate oxide layer having a first thickness; and
the gate region comprises:
a gate; and
a gate oxide layer on the body region, the gate oxide layer having a second thickness at least 1.4 times thicker than the first thickness.

5. The RF circuit of claim 1, wherein:
the first polarity is n+; and
the second polarity is p+.

6. The RF circuit of claim 1, wherein:
the first RF FET has a first RF FET gate length; and
the gate region has a gate length between 1.2 and 9 times the first RF FET gate length.

7. The RF circuit of claim 1, further comprising a first shunt ESDDFET coupled in a shunt connection between the first RF port and the first RF FET.

8. The RF circuit of claim 1, further comprising a second RF FET coupled in series to the first RF FET and a second RF port, and coupled in parallel to the RF common port.

9. The RF circuit of claim 8, further comprising a second shunt ESDDFET coupled in a shunt connection between the second RF port and the second RF FET.

10. The RF circuit of claim 8, wherein the second RF port comprises an electrostatic discharge (ESD) pulse port.

11. The RF circuit of claim 1, integrated in an RF front end module.

12. The RF circuit of claim 11, wherein the RF front end module is incorporated in at least one of a music player, a video player, an entertainment unit, a navigation device, a communications device, a personal digital assistant (PDA), a fixed location data unit, a mobile phone, and a portable computer.

13. A method for fabricating a radio frequency (RF) circuit, comprising:
fabricating a first RF field effect transistor (FET);
fabricating an electrostatic discharge dissipation (ESDD) FET (ESDDFET), comprising;
fabricating a body region of a first polarity, the body region not comprising:
a lightly doped pocket in the body region;
fabricating a drain region of a second polarity and adjacent to a first side of the body region;
fabricating a source region of the second polarity and adjacent to a second side of the body region opposite the first side; and
fabricating a gate region on the body region;
coupling the first RF FET in series to a first RF port; and
coupling the ESDDFET to a RF common port and in parallel with the first RF FET.

14. The method of claim 13, wherein:
fabricating the first RF FET further comprises:
fabricating a first RF FET gate oxide layer having a first thickness; and
fabricating the ESDDFET further comprises:
fabricating a gate oxide layer on the body region, the gate oxide layer having a second thickness at least 1.4 times thicker than the first thickness.

15. The method of claim 13, wherein the body region comprises:
a first lightly doped pocket of the second polarity in the body region adjacent to the drain region; and
a second lightly doped pocket of the second polarity in the body region adjacent to the source region,
wherein the body region does not comprise:
a halo region in the body region.

16. The method of claim 13, wherein:
fabricating the first RF FET further comprises:
fabricating an RF FET gate having a first RF FET gate length; and
fabricating the ESDDFET further comprises:
fabricating an ESDDFET gate having a gate length between 1.2 and 9 times the first RF FET gate length.

17. The method of claim 13, further comprising:
fabricating a first shunt ESDDFET; and
coupling the first shunt ESDDFET in a shunt connection between the first RF port and the first RF FET.

18. The method of claim 13, further comprising:
fabricating a second RF FET;
coupling the second RF FET in series to the first RF FET and a second RF port; and
coupling the second RF FET in parallel to the RF common port.

19. The method of claim 18, further comprising:
fabricating a second shunt ESDDFET; and
coupling the second shunt ESDDFET in a shunt connection between the second RF port and the second RF FET.

20. The method of claim 18, wherein the second RF port comprises an electrostatic discharge (ESD) pulse port.
